(19) United States
(12) Patent Application Publication
(10) Pub. No.: US 2011/0164640 A1
(43) Pub. Date: Jul. 7, 2011

(54) OPTICAL SEMICONDUCTOR DEVICE

(75) Inventors: Naoyuki Shimada, Tokyo (JP); Kenichi Ono, Tokyo (JP); Yoshihiko Hanamaki, Tokyo (JP)

(73) Assignee: MITSUBISHI ELECTRIC CORPORATION, Tokyo (JP)

(21) Appl. No.: 12/595,518

(22) PCT Filed: May 18, 2007
(86) PCT No.: PCT/JP2007/060224

§ 371 Date: Oct. 12, 2009

(51) Int. Cl. H01S 5/343; H01S 5/022; H01L 33/06

(52) U.S. Cl. 372/45.011; 257/13; 257/E33.005

(57) ABSTRACT

An optical semiconductor device comprises: a semiconductor light emitting element including semiconductor layers, including an active layer having a quantum well structure and epitaxially grown on a semiconductor substrate; and a submount on which the semiconductor light emitting element is mounted. Strain in the active layer after mounting the semiconductor light emitting element on the submount is larger than strain in the active layer after epitaxial growth of the active layer. The strain in the active layer during the epitaxial growth results in the surface of the semiconductor layers being a mirror surface. The strain in the active layer after the semiconductor light emitting element is mounted on the submount would not result in a mirror surface if present in the active layer at the epitaxial growth.

### TECHNICAL FIELD

The present invention relates to an optical semiconductor device wherein a semiconductor light-emitting device such as a semiconductor laser array, a semiconductor laser, or a light-emitting diode is mounted on a submount, and more particularly, to an optical semiconductor device capable of obtaining a high optical output.

### BACKGROUND ART

An optical semiconductor device wherein a semiconductor light-emitting device such as a semiconductor laser array, a semiconductor laser, or a light-emitting diode is mounted on a submount using solder is being used. Conventionally, the submount having a coefficient of thermal expansion which is near as possible to a coefficient of thermal expansion of the substrate material of the semiconductor light emitting element has been used, so that a stress is not applied to the semiconductor light-emitting device from the standpoint of the reliability. In this case, after the semiconductor light emitting element and the submount are bonded together at a temperature equal to or higher than the melting point of the solder, even if the temperature is cooled down to room temperature, a large thermal stress is not applied to the semiconductor light emitting element.

It is known that favorable characteristics such as a low threshold current or a large optical output can be obtained by providing a strain to the active layer of the semiconductor light emitting element so as to change the energy band structure (e.g., refer to Patent Document 1).
[Patent Document 1] Japanese Patent Application Laid-Open No. 07-115249

### DISCLOSURE OF THE INVENTION

### Problem to be Solved by the Invention

Conventionally, a strain was provided in the active layer by epitaxially growing crystals having different lattice constants on the same substrate while changing crystal compositions. However, when the difference among the lattice constants is too large and the strain quantity is larger than the critical strain, the crystalline becomes poor due to the lattice relaxation. Therefore, the favorable characteristics and the favorable reliability such as a low threshold current or a high optical output could not be obtained.

For example, even if the GaInP layer and the GaAs substrate are lattice-matched each other at room temperature, the tensile strain corresponding to the misfit which approximates to −0.1% at the epitaxial growth temperature is provided in the GaInP layer because of the difference of coefficients of thermal expansion between GaAs and GaInP. Therefore, the critical strain at the epitaxial growth temperature is smaller than the critical strain at ordinary temperature. Even if the stress is equal to or lower than the critical strain quantity of the material, because of the growth mode problem in the epitaxial growth, the favorable surface morphology may not be obtained. As described above, because the strain quantity which can be provided in the epitaxial growth process is limited, the favorable characteristics such as low threshold current or a high optical output might not be obtained.

The present invention has been implemented to solve the above described problems and it is an object of the present invention to provide an optical semiconductor device capable of obtaining a high optical output.

### Means for Solving the Problems

An optical semiconductor device comprises: a semiconductor light emitting element provided with semiconductor layers including an active layer having a quantum well structure and being epitaxially grown on a semiconductor substrate; and a submount on which the semiconductor light emitting element is mounted; wherein a strain quantity residing in the active layer after mounting the semiconductor light emitting element on the submount is larger than a strain quantity residing in the active layer after the epitaxial growth; the strain quantity residing in the active layer during the epitaxial growth is a value by which the surface of the semiconductor layers becomes a mirror surface; and the strain quantity residing in the active layer after the semiconductor light emitting element is mounted on the submount is a value by which the surface of the semiconductor layers does not become a mirror surface if the active layer has the value after the epitaxial growth.

### Effect of the Invention

The present invention makes it possible to realize an optical semiconductor device capable of obtaining a high optical output.

### BRIEF DESCRIPTION OF THE DRAWINGS

FIG. 1 is a perspective view showing an optical semiconductor device according to the first embodiment of the present invention.

FIG. 2 shows the relationships between the critical strain quantity and the critical thickness of the optical semiconductor device according to the first embodiment of the present invention.

FIG. 3 is a sectional view showing the stress applied to the semiconductor laser array and the submount in the optical semiconductor device according to the first embodiment of the present invention.

FIG. 4 shows characteristics of the semiconductor laser element that is obtained when the thickness of the submount is changed.

FIG. 5 is a sectional view showing the stress applied to the semiconductor laser array and the submount in the optical semiconductor device according to the third embodiment of the present invention.

FIG. 6 is a perspective view showing an optical semiconductor device according to the fourth embodiment of the present invention.

FIG. 7 is a perspective view showing an optical semiconductor device according to the fifth embodiment of the present invention.

### DESCRIPTION OF REFERENCE NUMERALS

11 semiconductor laser array (semiconductor light emitting element)
12 GaAs substrate (semiconductor substrate)
13,15 AlGaInP layer
14 GaInP/AlGaInP quantum well layer (active layer)
17 AuSn eutectic solder
18 submount
21 semiconductor laser (semiconductor light emitting element)
22 semiconductor light emitting diode (semiconductor light emitting element)

### BEST MODE FOR CARRYING OUT THE INVENTION

Embodiments of the present invention will be described with reference to the drawings. In the drawings, the same or corresponding parts will be denoted by the same numerals, and the description thereof may be simplified or omitted.

### Embodiment 1

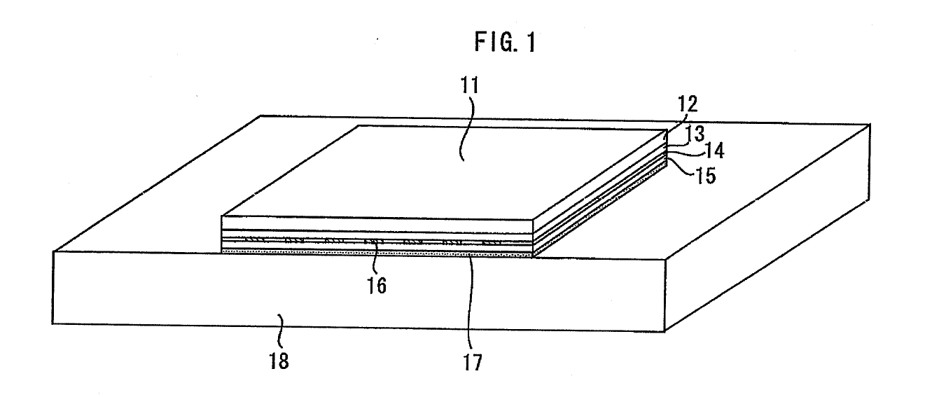

FIG. 1 is a perspective view showing an optical semiconductor device according to the first embodiment of the present invention. In the semiconductor laser array 11 (semiconductor light emitting element), an AlGaInP layer 13 including a cladding layer and a guide layer, GaInP/AlGaInP quantum well layer 14 acting as an active layer having a quantum well structure, and an AlGaInP layer 15 including a cladding layer and a guide layer are sequentially epitaxially grown on a GaAs substrate 12 (semiconductor substrate) using the MOCVD method. A strain quantity residing in the active layer during the epitaxial growth process corresponds to a value by which a surface of the semiconductor layers becomes a mirror surface and is not larger than the critical strain quantity at the epitaxial temperature. The active layer may have a multiquantum well structure. Further, the other semiconductor layers may be formed between the GaAs substrate 12 and the AlGaInP layer 13 or on the AlGaInP layer 15.

A plurality of active areas 16 of a stripe shape for confining current are formed in the GaInP/AlGaInP quantum well layer 14 so as to form a laser array. Such as a stripe formed by etching of insulating film, partial high resistance realized by irradiating protons, a ridge structure, a buried ridge structure, or a buried hetero structure can be used as a manner for forming the active layer 16 of a stripe shape. Here, the stripe formed by etching of insulating film is used.

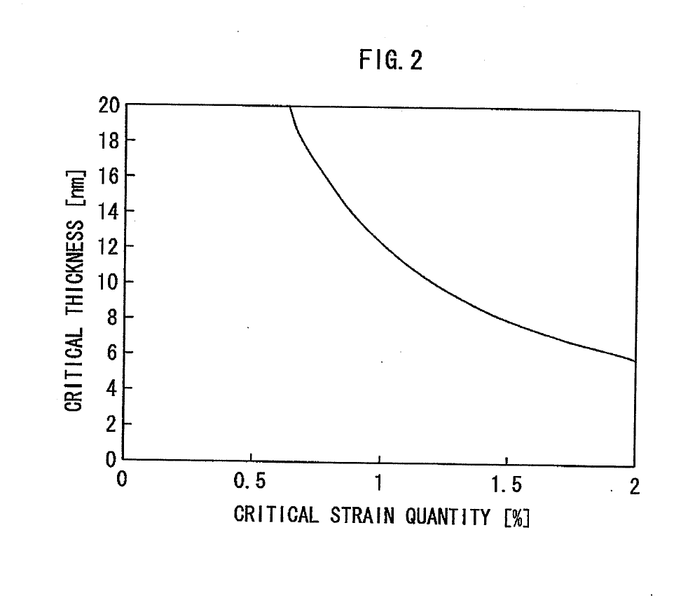

The active layer has a tensile strain which is a bit smaller than the critical strain in the epitaxial growth temperature. Here, the equation of Van der Merwe is known as an equation representing the relation between the critical thickness and the critical strain (document R. People and J. C. Bean). That is, if a critical thickness is hc [nm] and an absolute value of a critical strain quantity is fc [%], hc=A/fc is satisfied provided that fc<4 and A is a constant. It is founded that A=12.5 by a surface inspection of the optical semiconductor device according to the first embodiment executed after the epitaxial growth. FIG. 2 shows the relationships between the critical strain quantity and the critical thickness of the optical semiconductor device according to the first embodiment of the present invention.

The semiconductor laser array 11 is mounted on the SiC submount 18 using an AuSn eutectic solder 17. An epitaxial growth surface (junction side) of the semiconductor laser array 11 having the active layer is faced to the submount 18. The AuSn eutectic solder 17 used for mounting has a high melting point, thereby being hard to be deformed. As a result, a thermal stress is easily provided to the active layer of the semiconductor laser array 11.

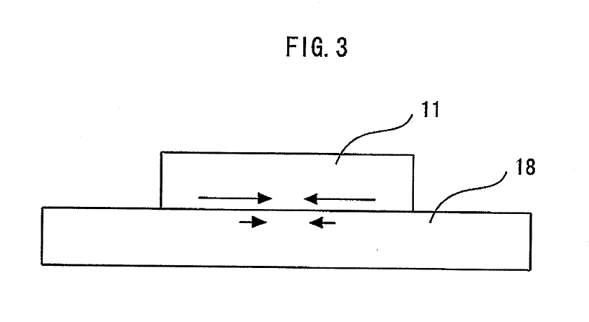

The coefficient of thermal expansion of SiC is about 3 [10⁻⁶/K] and is smaller than the coefficient of thermal expansion of GaAs which is about 6[10⁻⁶/K]. As a result, the semiconductor laser array 11 is going to shrink more greatly than the submount 18 as shown in FIG. 3 when the temperature drops until the room temperature after the two of them are connected each other at a temperature being equal to or higher than the melting point of the AuSn eutectic solder 17. However, because they are jointed by the AuSn eutectic solder 17, tensile strain is provided to the epitaxial growth layer of the semiconductor laser array 11 so as to enlarge the tensile strain provided to the GaInP/AlGaInP quantum well layer 14 after the epitaxial growth process. That is, a strain quantity residing in the active layer after the semiconductor laser array 11 is mounted on the submount 18 is larger than a strain quantity residing in the active layer after the epitaxial growth.

This increase of the tensile strain is performed after the epitaxial growth at the temperature equal to or lower than 300° C. which is significantly lower than the temperature during the epitaxial growth of about 500-800° C. Thus, the critical strain becomes larger than the critical strain under the epitaxial growth temperature. As a result, the strain quantity of the tensile strain, which can not be obtained by controlling the strain quantity in the epitaxial growth process, can be provided. Therefore, the strain quantity residing in the active layer after the semiconductor laser array 11 is mounted on the submount 18 is set to a value by which the surface of the semiconductor layers does not become a mirror surface under a situation in which the strain quantity is tried to be obtained during the epitaxial growth. This strain quantity is not larger than a critical strain quantity at ordinary temperature but larger than the critical strain quantity at the epitaxial temperature.

If a thickness of the active layer is h [nm] and an absolute value of a strain quantity of the active layer is f [%], f<4 and h≦12.5/f are satisfied after a stage of the epitaxial growth, and h>12.5/f is satisfied after the semiconductor laser array 11 is mounted on the submount 18.

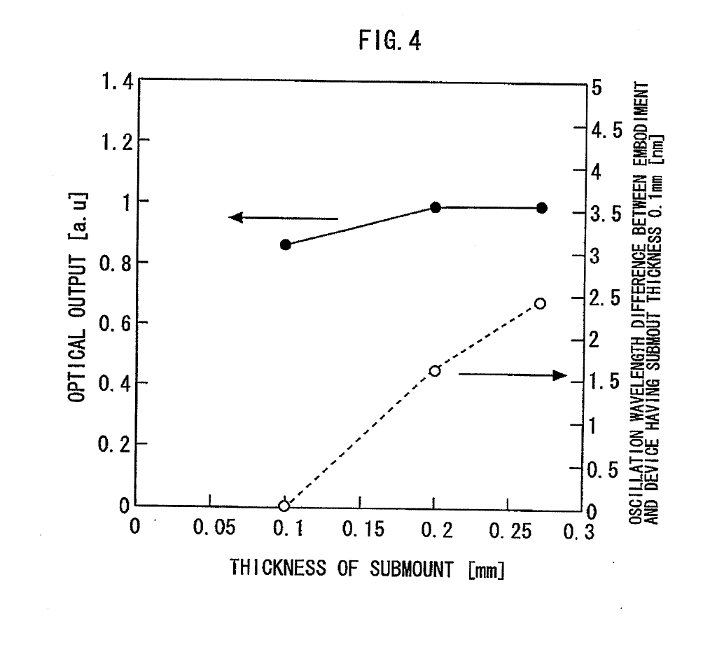

FIG. 4 shows characteristics of the semiconductor laser element that is obtained when the thickness of the submount is changed. The thicker the submount, the larger the effect of thermal stress caused by the submount. As a result, it is known that a high optical output can be obtained.

As described above, the stress is mechanically provided after the epitaxial growth by thermal stress, which has not been actively used in prior art and is cased by the connection between the semiconductor laser array and the submount after the epitaxial growth, in addition to providing the stress in the epitaxial growth. Thus, the tensile strain of the active layer can be increased. As a result, a high optical output can be obtained. The provided stress must be less than a value which causes a break of the crystal.

### Embodiment 2

In the second embodiment of the present invention, the GaAs substrate 12 is used. GaAsP in which a tensile strain is provided is used as the active layer instead of the GaInP/AlGaInP quantum well layer 14. AlN (its coefficient of thermal expansion is about 4-5 [10⁻⁶/K]) is used as the submount 18. All other components are similar to those described in connection with the first embodiment.

Thereby, as in the first embodiment, the stress is mechanically provided by thermal stress cased by the connection between the semiconductor laser array and the submount after the epitaxial growth. Therefore, because the tensile strain of the active layer can be increased, a high optical output can be obtained.

### Embodiment 3

In the third embodiment of the present invention, the GaAs substrate 12 is used. InGaAsP in which a compressive strain is provided is used as the active layer instead of the GaInP/AlGaInP quantum well layer 14. CuW whose coefficient of thermal expansion is larger than GaAs is used as the submount 18. All other components are similar to those described in connection with the first embodiment.

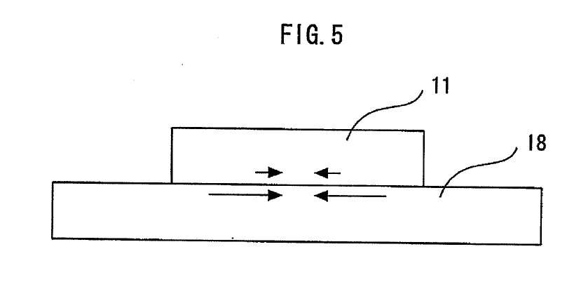

Thereby, as FIG. 5 shows, the submount 18 is going to shrink more greatly than the semiconductor laser array 11. Therefore, because the compressive strain of the active layer can be increased, a high optical output can be obtained.

### Embodiment 4

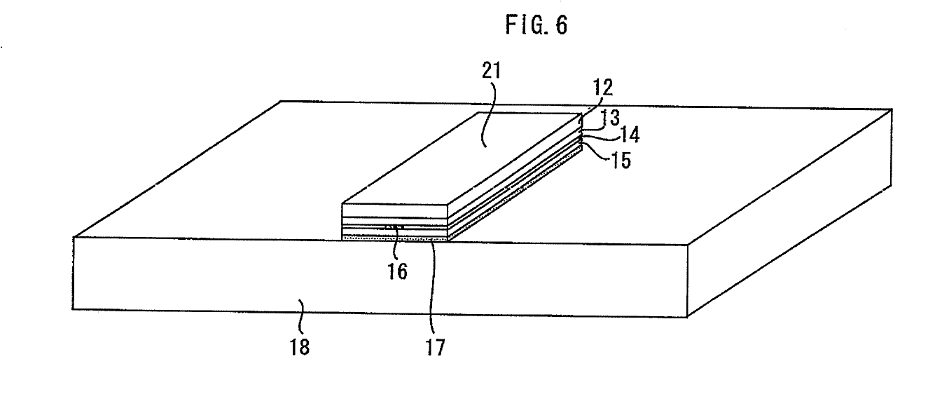

FIG. 6 is a perspective view showing an optical semiconductor device according to the fourth embodiment of the present invention. The semiconductor laser 21 (semiconductor light emitting element) is not an array used in the first embodiment, but is a single semiconductor laser which has a chip and a emitting stripe portion. All other components are similar to those described in connection with the first to third embodiments. Even when the optical semiconductor device is the single semiconductor laser, by using thermal stress due to the mismatch between coefficient of thermal expansion of the semiconductor light emitting element and coefficient of thermal expansion of submount, the strain quantity of the active layer can be increased and a high optical output can be obtained as in the case of the first to the third embodiments.

### Embodiment 5

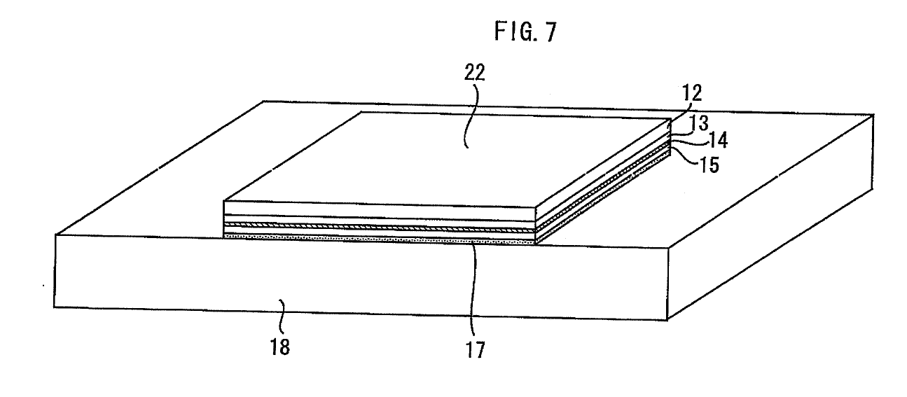

FIG. 7 is a perspective view showing an optical semiconductor device according to the fifth embodiment of the present invention. A semiconductor light emitting diode 22 (semiconductor light emitting element) has semiconductor layers epitaxially grown on a GaAs substrate 12. The semiconductor layers includes a GaInP/AlGaInP quantum well layer 14 which is an active layer having a quantum well structure. Even when the optical semiconductor device is a light emitting diode, by using thermal stress due to the mismatch between coefficient of thermal expansion of the semiconductor light emitting element and coefficient of thermal expansion of the submount, the strain quantity of the active layer can be increased and a high optical output can be obtained as in the case of the first to the third embodiments.

### INDUSTRIAL APPLICABILITY

In the optical semiconductor device wherein the semiconductor light emitting element such as the semiconductor laser array, the semiconductor laser, or the semiconductor light emitting diode is mounted on the submount, the strain quantity in the active layer can be increased by using thermal stress due to the mismatch between coefficient of thermal expansion of the semiconductor light emitting element and coefficient of thermal expansion of the submount, and the high optical output can be obtained.

1. An optical semiconductor device comprising:
a semiconductor light emitting element comprising a semiconductor substrate and semiconductor layers, the semiconductor layers including an active layer having a quantum well structure that is epitaxial with the semiconductor substrate; and
a submount on which the semiconductor light emitting element is mounted, wherein
strain in the active layer after mounting the semiconductor light emitting element on the submount is larger than strain in the active layer immediately after epitaxial growth of the active layer,
the strain in the active layer during the epitaxial growth of the active layer results in the semiconductor layers having a mirror surface; and
the strain in the active layer after the semiconductor light emitting element is mounted on the submount would not result in the semiconductor layers having a mirror surface if that strain were in the active layer at the epitaxial growth.

2. An optical semiconductor device comprising:
a semiconductor light emitting element comprising a semiconductor substrate and semiconductor layers, the semiconductor layers including an active layer having a quantum well structure and that is epitaxial with the semiconductor substrate, and
a submount on which the semiconductor light emitting element is mounted, wherein
strain in the active layer after the semiconductor light emitting element is mounted on the submount is larger than strain in the active layer after epitaxial growth of the active layer,
the strain in the active layer during the epitaxial growth is not larger than a critical strain the temperature of the epitaxial group of the active layer, and
the strain in the active layer after the semiconductor light emitting element is mounted on the submount is not larger than a critical strain at room temperature but larger than the critical strain at the temperature of the epitaxial growth of the active layer.

3. The optical semiconductor device according to claim 1, wherein the semiconductor light emitting element is mounted on the submount with an epitaxial growth surface facing the submount.

4. The optical semiconductor device according to claim 1, including AuSn eutectic solder bonding the semiconductor light emitting element to the submount.

5. The optical semiconductor device according to claim 1, wherein the semiconductor light emitting element is selected from the group consisting of semiconductor laser arrays, semiconductor lasers, and semiconductor light emitting diodes.

6. The optical semiconductor device according to claim 1, wherein the strain in the active layer is a tensile strain.

7. The optical semiconductor device according to claim 6, wherein the submount is one of SiC and AlN.

8. The optical semiconductor device according to claim 6, wherein the semiconductor substrate is GaAs, and the active layer is GaInP.

9. The optical semiconductor device according to claim 8, wherein the semiconductor layer further includes one of a cladding layer and a guide layer of AlGaInP.

10. The optical semiconductor device according to claim 8, wherein if the active layer has a thickness h in nm and absolute value of the strain in the active layer is f in percent, f<4%, and h≦12.5/f is satisfied after the epitaxial growth of the active layer, and h>12.5/f is satisfied after the semiconductor light emitting element is mounted on the submount.

11. The optical semiconductor device according to claim 6, wherein the semiconductor substrate is GaAs, and the active layer is GaAsP.

12. The optical semiconductor device according to claim 1, wherein the strain in the active layer is a compressive strain.

13. The optical semiconductor device according to claim 12, wherein the semiconductor substrate is GaAs, and the active layer is InGaAsP.

14. The optical semiconductor device according to claim 12, wherein the submount is CuW.
